(19) United States
(12) Patent Application Publication
(10) Pub. No.: US 2008/0223430 A1
(43) Pub. Date: Sep. 18, 2008

(54) Buffer layer for front electrode structure in photovoltaic device or the like

(75) Inventors: Alexey Krasnov, Canton, MI (US); Yiwei Lu, Ann Arbor, MI (US)

Correspondence Address: NIXON & VANDERHYE, PC, 901 NORTH GLEBE ROAD, 11TH FLOOR, ARLINGTON, VA, 22203, US

(73) Assignee: Guardian Industries Corp., Auburn Hills, MI (US)

(21) Appl. No.: 11/717,787

(22) Filed: Mar. 14, 2007

(51) Int. Cl. H01L 31/042; C23C 14/00

(52) U.S. Cl. 136/244; 204/192.1

(57) ABSTRACT

Certain example embodiments of this invention relate to an electrode structure (e.g., front electrode structure) for use in a photovoltaic device or the like. In certain example embodiments, a buffer layer (e.g., of or including tin oxide) is provided between the front electrode and the semiconductor absorber film in a photovoltaic device. The buffer layer may be deposited via sputtering, and may or may not be doped in certain example instances. In an example context of use in CdS/CdTe photovoltaic devices, the buffer layer is advantageous in that it (one or more of): (a) provides a good work-function match to a possible CdS/CdTe film and the front electrode; (b) provides good durability in that it is better able to withstand attacks of sulfur vapors at elevated temperatures during possible CdS/CdTe processing; (c) may be at least partially conductive; and/or (d) provides good mechanical durability.

Certain example embodiments of this invention relate to a buffer layer provided in connection with a front electrode in a photovoltaic device or the like. In certain example embodiments, tin oxide based buffer layer is provided between the front electrode and the semiconductor absorber film in a photovoltaic device. The tin oxide based buffer layer may be deposited via sputtering, and may or may not be doped in certain example instances. In an example context of use in CdS/CdTe photovoltaic devices, the tin oxide based buffer layer is advantageous in that it (one or more of): (a) provides a good work-function match to the CdS/CdTe film and the front electrode; (b) provides good durability in that it is better able to withstand attacks of sulfur vapors at elevated temperatures during CdS/CdTe processing; (c) may be conductive; and/or (d) provides good mechanical durability.

### BACKGROUND AND SUMMARY OF EXAMPLE EMBODIMENTS OF INVENTION

Photovoltaic devices are known in the art (e.g., see U.S. Pat. Nos. 6,784,361, 6,288,325, 6,613,603 and 6,123,824, the disclosures of which are hereby incorporated herein by reference). Amorphous silicon (a-Si) and CdTe type (including CdS/CdTe) photovoltaic devices, for example, each include a front contact or electrode.

Pyrolitic SnO₂:F transparent conductive oxide (TCO) is often used as a front transparent electrode in photovoltaic devices. One advantage of pyrolitic SnO₂:F for use as a TCO front electrode in photovoltaic devices is that it is able to withstand high processing temperatures used in making the devices. However, pyrolytically deposited fluorine-doped tin oxide TCOs have several drawbacks, such as considerable variation in sheet resistance across the lite and from batch to batch, and excessive surface roughness in certain instances. The former drawback has a significant impact on voltage variation of completed photovoltaic devices, whereas the latter drawback can result in undesirably high numbers of pinholes in the TCO which in turn may require an increased thickness of CdS between CdTe and the TCO.

Thus, it will be appreciated that there exists a need in the art for a more efficient and/or improved photovoltaic device, and/or front electrode structure therefor. Moreover, in certain example embodiments of this invention, there may also exist a need in the art for a technique for making or forming a TCO electrode structure.

Certain example embodiments of this invention relate to a buffer layer provided in connection with a front electrode in a photovoltaic device or the like. In certain example embodiments, a front electrode structure includes a tin oxide based buffer layer that is provided between the front electrode and the semiconductor absorber film in a photovoltaic device. The tin oxide based buffer layer may be deposited via sputtering or the like, and may or may not be doped in certain example instances. In an example context of CdS/CdTe photovoltaic devices, the tin oxide based buffer layer is advantageous in that it (one or more of): (a) provides a good work-function match to the CdS/CdTe film and the front electrode; (b) provides good durability in that it is able to adequately withstand attacks of sulfur vapors at elevated temperatures during CdS/CdTe processing; (c) may be conductive; and/or (d) provides good mechanical durability.

In certain example embodiments, the electrode structure (including the electrode and the buffer layer) may be used as any suitable electrode structure in any suitable electronic device, such as a photovoltaic device, electro-optical device, or the like. In certain example embodiments of this invention, the electrode structure may have a sheet resistance (Rₛ) of from about 7-50 ohms/square, more preferably from about 10-25 ohms/square, and most preferably from about 10-15 ohms/square using a reference example non-limiting thickness of from about 1,000 to 10,000 angstroms, more preferably from about 1,000 to 2,000 Å.

In certain example embodiments of this invention, there is provided a photovoltaic device comprising: a front glass substrate; an active semiconductor film; an electrically conductive and substantially transparent front electrode located between at least the front glass substrate and the semiconductor film; and a buffer film comprising tin oxide located between the front electrode and the semiconductor film.

In other example embodiments of this invention, there is provided an electrode structure for use in an electronic device, the electrode structure comprising: an electrically conductive and substantially transparent electrode located between at least a substrate and a semiconductor film; and a buffer film comprising tin oxide located between the electrode and the semiconductor film, wherein the buffer film has a conductivity less than that of the electrode.

In still further example embodiments of this invention, there is provided a method of making a photovoltaic device, the method comprising: providing a glass substrate; sputtering at least one target in an atmosphere in order to deposit a substantially transparent conductive electrode on the glass substrate; sputtering at least one target comprising tin in order to deposit a buffer film comprising tin oxide on the glass substrate over at least the conductive electrode, thereby forming an electrode structure on the glass substrate; and forming a photovoltaic device in which the electrode structure is coupled to an active semiconductor film in order to form the photovoltaic device.

### BRIEF DESCRIPTION OF THE DRAWINGS

FIG. 1 is a cross sectional view of an example photovoltaic device according to an example embodiment of this invention.

### DETAILED DESCRIPTION OF EXAMPLE EMBODIMENTS OF THE INVENTION

Referring now more particularly to the drawings in which like reference numerals indicate like parts throughout the several views.

Photovoltaic devices such as solar cells convert solar radiation and other light into usable electrical energy. The energy conversion occurs typically as the result of the photovoltaic effect. Solar radiation (e.g., sunlight) impinging on a photovoltaic device and absorbed by an active region of semiconductor material (e.g., a semiconductor film including one or more semiconductor layers such as a-Si layers, or any other suitable semiconductor material such as CdS, CdTe and/or the like) generates electron-hole pairs in the active region. The electrons and holes may be separated by an electric field of a junction in the photovoltaic device. The separation of the electrons and holes by the junction results in the generation of an electric current and voltage. In certain example embodiments, the electrons flow toward the region of the semiconductor material having n-type conductivity, and holes flow toward the region of the semiconductor having p-type conductivity. Current can flow through an external circuit connecting the n-type region to the p-type region as light continues to generate electron-hole pairs in the photovoltaic device.

While certain example embodiments of this invention may be especially useful in the context of CdS/CdTe type photovoltaic devices, this invention is not so limited. Electrode structures of this invention may be applicable to other types of photovoltaic devices as well in certain instances. For example, in certain example embodiments, single junction amorphous silicon (a-Si) photovoltaic devices include three semiconductor layers which make up a semiconductor film. In particular, a p-layer, an n-layer and an i-layer which is intrinsic. The amorphous silicon film (which may include one or more layers such as p, n and i type layers) may be of hydrogenated amorphous silicon in certain instances, but may also be of or include hydrogenated amorphous silicon carbon or hydrogenated amorphous silicon germanium, or the like, in certain example embodiments of this invention. For example and without limitation, when a photon of light is absorbed in the i-layer it gives rise to a unit of electrical current (an electron-hole pair). The p and n-layers, which contain charged dopant ions, set up an electric field across the i-layer which draws the electric charge out of the i-layer and sends it to an optional external circuit where it can provide power for electrical components. It is noted that while certain example embodiments of this invention may be directed toward amorphous-silicon based photovoltaic devices, this invention is not so limited and may be used in conjunction with other types of photovoltaic devices in certain instances including but not limited to devices including other types of semiconductor material, tandem thin-film solar cells, and the like. Moreover, electrode structures according to different embodiments of this invention may also be used in connection with CIS/CIGS and/or tandem a-Si type photovoltaic devices.

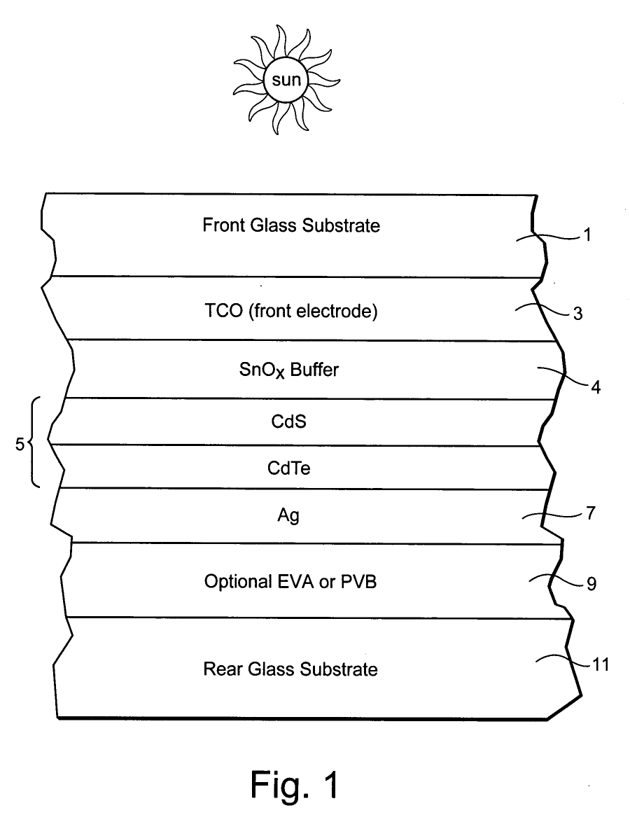

FIG. 1 is a cross sectional view of a photovoltaic device according to an example embodiment of this invention. The photovoltaic device includes transparent front substrate 1 of glass or the like, front electrode or contact 3 which may be of or include a transparent conductive oxide (TCO) such as indium-tin-oxide (ITO), ZnOₓ, ZnAlOₓ, InZnOₓ, and/or the like, buffer film 4 of one or more layers which may also be a TCO, active semiconductor film 5 of one or more semiconductor layers, optional back electrode and/or reflector 7 which may be of a metal such as silver or alternatively may be of or include a TCO, an optional encapsulant 9 or adhesive of a material such as ethyl vinyl acetate (EVA), polyvinyl butyral (PVB), or the like, and an optional rear substrate 11 of a material such as glass or the like. The semiconductor layer(s) of film 5 may be of or include one or more of CdTe, CdS, a-Si, or another other suitable semiconductor material, in different example embodiments of this invention. Of course, other layer(s) which are not shown may be provided in the device, such as between the front glass substrate 1 and the front electrode 3, or between other layers of the device.

While the front electrode 3 may be of or include a transparent conductive oxide (TCO) such as indium-tin-oxide (ITO), ZnOₓ, ZnAlOₓ (Al doped zinc oxide), and/or InZnOₓ in certain example instances, this invention is not so limited as other materials or layer(s) may instead be used in forming the front electrode 3 in different example embodiments of this invention. For example, a coating including at least one silver-based layer (and possibly other layer(s)) may be used as the electrode 3 in certain example instances.

Buffer film 4 may be of or including TCO of or including tin oxide in certain example embodiments of this invention. In certain example embodiments, the transparent buffer film 4 may include only one layer, and may be provided between and directly contacting the semiconductor absorber 5 and the highly conductive front electrode 3 of the photovoltaic device. The tin oxide based buffer film 4 may be deposited via sputtering or the like, and may or may not be doped in certain example instances. For instance, the tin oxide based buffer film 4 may be doped with Sb (e.g., 0.01 to 10%, more preferably from about 0.5 to 8%) or the like in certain example instances in order to increase the buffer film's electrical conductivity. Moreover, improved results are achieved by sputter-depositing the tin oxide based buffer film 4; compared to if it were deposited via pyrolysis, because sputter-deposition provides for a more uniform surface and predictable sheet resistance characteristics of the buffer film 4. Thus, voltage variations in completed devices may be improved by depositing the film 4 via sputtering or the like, and the number of pinholes may be reduced. In general, the conductivity of the buffer film 4 is less than that of the front electrode 3 but is more than that of a dielectric.

In certain example embodiments, the front electrode 3 is from about 100 to 10,000 Å thick, more preferably from about 500 to 5,000 Å thick, even more preferably from about 1,000 to 4,000 Å thick, even more preferably from about 2,000 to 4,000 Å thick, with an example thickness being about 3,000 Å. In certain example embodiments of this invention, the electrode 3 may have a sheet resistance (Rₛ) of from about 7-50 ohms/square, more preferably from about 10-25 ohms/square, and most preferably from about 10-15 ohms/square using a reference example non-limiting thickness of from about 1,000 to 2,000 angstroms.

In certain example embodiments, the buffer film 4 is from about 100 to 5,000 Å thick, more preferably from about 100 to 1,000 Å thick, even more preferably from about 150 to 600 Å thick, with an example thickness being about 300 Å. In certain example embodiments, the buffer film 4 is electrically conductive (although it can be insulating in alternative embodiments). In certain example embodiments, the buffer film 4 has a resistivity of from about 0.0001 to 100 kOhm-cm, more preferably from about 0.005 to 50 kOhm-cm, still more preferably from about 1 to 10 kOhm-cm, with an example being about 5 kOhm-cm.

In certain example embodiments, the buffer film 4 may have a work-function of from about 4.0 to 5.7 eV, more preferably from about 4.3 to 5.2 eV, and possibly from about 4.5 to 5.0 eV. This may provide for good matching or substantial matching with CdS/CdTe of the semiconductor absorber 5.

In an example context of use in CdS/CdTe photovoltaic devices, the tin oxide based buffer film 4 is advantageous in that it (one or more of): (a) provides a good work-function match to the CdS/CdTe film 5 and the front electrode 3; (b) provides good durability in that it is better able to withstand attacks of sulfur vapors at elevated temperatures during CdS/CdTe 5 processing which may be used in making the device; (c) may be conductive; and/or (d) provides good mechanical durability. Accordingly, in certain example embodiments, the photovoltaic device combines excellent matching properties of a low-conductivity tin oxide based film 4 with excellent conductivity properties of a high-conductivity front electrode 3. The result is an improved overall photovoltaic device.

In certain example embodiments of this invention, in making the photovoltaic device, the electrode structure is first formed. For example, a TCO front electrode (e.g., ITO and/or ZnOₓ) 3 may first be sputter-deposited on the glass substrate 1 at room temperature or proximate room temperature, although elevated temperatures may be used. Then, the tin oxide based buffer film 4 (e.g., SnOₓ, where 1.0>x>0.2, more preferably 0.95>x>0.4; and/or Sb-doped SnOₓ, same x values) is sputter-deposited on the glass substrate 1 at approximately room temperature (although elevated temperatures may be used) over the highly conductive front electrode 3. The buffer film 4 may be substoichiometric in certain example embodiments, and may be electrically conductive—albeit less conductive that the electrode 3 in certain example instances. The glass substrate 1 with the front electrode 3 and buffer film 4 thereon may or may not be thermally tempered in different instances.

In certain example embodiments, the sputter-deposited buffer film 4 may be deposited on the glass substrate 1, over the highly conductive electrode 3, as an amorphous or polycrystalline film depending on the deposition conditions. In certain example embodiments, the buffer film 4 may be amorphous or substantially amorphous as deposited, and then may be transformed into a polycrystalline or substantially polycrystalline film 4 following thermal tempering of the glass substrate 1 with the films 3, 4 thereon.

Front glass substrate 1 and/or rear substrate 11 may be made of soda-lime-silica based glass in certain example embodiments of this invention. While substrates 1, 11 may be of glass in certain example embodiments of this invention, other materials such as quartz or the like may instead be used. Like electrode 3 and/or film 4, substrate 1 may or may not be patterned in different example embodiments of this invention. Moreover, rear substrate or superstrate 11 is optional in certain instances. Glass 1 and/or 11 may or may not be thermally tempered in different embodiments of this invention.

The active semiconductor region or film 5 may include one or more layers, and may be of any suitable material. For example, the semiconductor absorber film 5 may include CdS and/or CdTe layer(s) in certain example embodiments. As another example, the active semiconductor film 5 of one type of single junction amorphous silicon (a-Si) photovoltaic device includes three semiconductor layers, namely a p-layer, an n-layer and an i-layer. These amorphous silicon based layers of film 5 may be of hydrogenated amorphous silicon in certain instances, but may also be of or include hydrogenated amorphous silicon carbon or hydrogenated amorphous silicon germanium, or other suitable material(s) in certain example embodiments of this invention. It is possible for the active region 5 to be of a double-junction type in alternative embodiments of this invention.

Back contact, reflector and/or electrode 7 of the photovoltaic device may be of any suitable electrically conductive material. For example and without limitation, the optional back contact, reflector and/or electrode 7 may be of a TCO and/or a metal in certain instances. Example metals include Ag as shown in FIG. 1. Example TCO materials for use as back contact or electrode 7 include indium zinc oxide, indium-tin-oxide (ITO), tin oxide, and/or zinc oxide which may be doped with aluminum (which may or may not be doped with silver).

In certain example embodiments of this invention, it has been found that by sputtering a ceramic target(s) in a particular type of atmosphere to form TCO coating 3, the electro-optical properties of the resulting TCO coating/electrode 3 can be optimized. For example, using a particular type of atmosphere in the sputtering process can permit the resulting TCO electrode 3 to more readily withstand subsequent high temperature processing which may be used during manufacture of the photovoltaic device. Moreover, processing energy resulting from the high temperature(s) may also optionally be used to improve crystallinity characteristics of the TCO coating/electrode 3. In certain example embodiments of this invention, the TCO coating/electrode 3 (e.g., of or including zinc oxide, zinc aluminum oxide, and/or indium-tin-oxide, or the like) may be sputter-deposited using a ceramic sputtering target(s) in an atmosphere including both argon (Ar) and oxygen (O₂) gases. For example, when sputtering depositing a layer of zinc oxide for TCO electrode 3, the ceramic target(s) used in such sputtering can be of zinc oxide; when sputter depositing a layer of zinc aluminum oxide for TCO electrode 3, the ceramic target(s) used in such sputtering can be of zinc aluminum oxide; and/or when sputter depositing a layer of indium-tin-oxide (ITO) for TCO electrode 3, the ceramic target(s) used in such sputtering can be of ITO. In certain example embodiments, the oxygen content of the gaseous atmosphere used in sputtering to form coating/electrode 3 is adjusted so as to optimize the electro-optical properties of the resulting TCO coating/electrode 3. In certain example embodiments, the atmosphere used in sputter-depositing a zinc oxide based or inclusive TCO coating/electrode 3 (which may optionally be doped with Al or the like) has an oxygen gas to total gas ratio (e.g., O₂/(Ar+O₂) ratio) of from 0 to 0.0025, more preferably from about 0.00001 to 0.0025, still more preferably from about 0.0001 to 0.002, even more preferably from about 0.0001 to 0.0015, and most preferably from about 0.0001 to 0.0010, with an example ratio being about 0.0005. In such example embodiments, the TCO electrode 3 may consist or consist essentially of zinc oxide, or alternatively may be doped with a metal such as Al or the like. For example, in certain example instances, such a TCO electrode 3 may include from about 0-10% Al, more preferably from about 0.5-10% Al, even more preferably from about 1-5% Al, still more preferably from about 1-3% Al, with an example amount of Al dopant in electrode/coating 3 being about 2.0% (wt. %).

In other example embodiments, the atmosphere used in sputter-depositing an ITO based or inclusive TCO coating/electrode 3 has an oxygen gas to total gas ratio (e.g., O₂/(Ar+O₂) ratio) of from 0.003 to 0.017, more preferably from about 0.004 to 0.016, still more preferably from about 0.005 to 0.015, even more preferably from about 0.008 to 0.014, with an example ratio being about 0.011. In certain example instances, an ITO coating/electrode 3 may include in the metal portion thereof (made up of for example the total In and Sn content, not including oxygen content): from about 50-99% indium (In), more preferably from about 60-98% In, still more preferably from about 70-95% In, most preferably from about 80-95% In, with an example amount of In in the coating/electrode 3 being about 90% (wt. %); and from about 1-50% Sn, more preferably from about 2-40% Sn, even more preferably from about 5-30% Sn, still more preferably from about 5-20% Sn, with an example Sn amount being about 10% Sn (wt. %). Thus, in certain example embodiments, the coating/electrode 3 includes more In than Sn, more preferably at least twice at much In as Sn, even more preferably at least about five times as much In as Sn, and possibly about nine times as much In as Sn. For example, in an example ITO coating electrode, the In/Sn ratio may be about 90/10 wt % in certain example instances. The above percentages of In and Sn, and the above ratios, may also apply to the overall ITO based coating/electrode 3 in certain example embodiments.

In certain example embodiments, it has been found that the above gas ratios cause the electrical conductivity of the sputter-deposited TCO electrode/coating 3 to be improved before and/or after subsequent high temperature processing (e.g., high temperature processing used in photovoltaic device manufacturing). Example temperatures for the optional subsequent processing may include temperatures of at least about 220 degrees C. (e.g., for a-Si and/or micromorph photovoltaic devices), possibly of at least about 240 degrees C., possibly of at least about 500 degrees C., possibly of at least about 550 degrees C (e.g., for CdTe devices), and possibly of at least about 600 or 625 degrees C. Additionally, the resulting electrode 3 can realize reduced or no structural transformation at optional subsequent high temperatures. Moreover, it has also unexpectedly been found that these gas ratios are advantageous in that they allow the optional subsequent high temperature processing to be used to improve the crystallinity of the TCO coating/electrode 3 thereby resulting in a highly conductive and satisfactory TCO coating/electrode 3 which may be used in applications such as electrodes 3 (and possibly 4 and/or 7) in photovoltaic devices and the like. The sputtering may be performed at approximately room temperature in certain example embodiments, although other temperatures may be used in certain instances.

The ceramic target(s) used in sputter-depositing electrode/coating 3 and/or buffer film 4 may be of any suitable type in certain example embodiments of this invention. For example, rotating magnetron type targets or stationary planar targets may be used in certain example instances.

In certain example embodiments, the substantially transparent electrode 3 (and also the film 4) has a visible transmission of at least about 50%, more preferably of at least about 60%, even more preferably of at least about 70% or 80%. In certain example embodiments of this invention, the TCO front electrode or contact 3 is substantially free, or entirely free, of fluorine. This may be advantageous in certain example instances for pollutant issues.

An additional potential advantage of sputter-deposited TCO films for front electrodes/contacts 3 is that they may permit the integration of an anti-reflection and/or colour-compression coating (not shown) between the front electrode 3 and the glass substrate 1. The anti-reflection coating (not shown) may include one or multiple layers in different embodiments of this invention. For example, the anti-reflection coating (not shown) may include a high refractive index dielectric layer immediately adjacent the glass substrate 1 and another layer of a lower refractive index dielectric immediately adjacent the front electrode 3. Thus, since the front electrode 3 is on the glass substrate 1, it will be appreciated that the word “on” as used herein covers both directly on and indirectly on with other layers therebetween. In other example embodiments, an antireflective coating may be located on the major side/surface of glass substrate 1 closest to the viewer.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

1. A photovoltaic device comprising:
a front glass substrate;
an active semiconductor film;
an electrically conductive and substantially transparent front electrode located between at least the front glass substrate and the semiconductor film; and
a buffer film comprising tin oxide located between the front electrode and the semiconductor film.

2. The photovoltaic device of claim 1, wherein the buffer film directly contacts each of the front electrode and the semiconductor film.

3. The photovoltaic device of claim 1, wherein the buffer film has a work function of at least 4.3 eV.

4. The photovoltaic device of claim 1, wherein the buffer film comprising tin oxide is doped with Sb.

5. The photovoltaic device of claim 1, wherein the buffer film is from about 100 to 1,000 angstroms (Å) thick.

6. The photovoltaic device of claim 1, wherein the buffer film is from about 150 to 600 Å thick.

7. The photovoltaic device of claim 1, wherein the substantially transparent front electrode comprises one or more of: indium-tin-oxide, zinc oxide, zinc aluminum oxide, and/or indium zinc oxide.

8. The photovoltaic device of claim 1, wherein the buffer film consists essentially of tin oxide which may optionally be doped with Sb.

9. The photovoltaic device of claim 1, wherein the buffer film is conductive and substantially transparent.

10. The photovoltaic device of claim 1, wherein the buffer film is less conductive, and thus has higher resistivity, than the front electrode.

11. The photovoltaic device of claim 1, wherein the semiconductor film comprises CdS and/or CdTe.

12. The photovoltaic device of claim 1, further comprising a back electrode, wherein the active semiconductor film is provided between at least the front electrode and the back electrode.

13. The photovoltaic device of claim 1, wherein the buffer film has a work-function of from about 4.0 to 5.7 eV.

14. The photovoltaic device of claim 1, wherein the buffer film has a work-function of from about 4.3 to 5.2 eV.

15. The photovoltaic device of claim 1, wherein the buffer film has a work-function of from about 4.5 to 5.0 eV.

16. An electrode structure for use in an electronic device, the electrode structure comprising:
an electrically conductive and substantially transparent electrode located between at least a substrate and a semiconductor film; and
a buffer film comprising tin oxide located between the electrode and the semiconductor film, wherein the buffer film has a conductivity less than that of the electrode.

17. The photovoltaic device of claim 16, wherein the buffer film directly contacts each of the electrode and the semiconductor film.

18. A method of making a photovoltaic device, the method comprising:
providing a glass substrate;
sputtering at least one target in an atmosphere in order to deposit a substantially transparent conductive electrode on the glass substrate;
sputtering at least one target comprising tin in order to deposit a buffer film comprising tin oxide on the glass substrate over at least the conductive electrode, thereby forming an electrode structure on the glass substrate; and
forming a photovoltaic device in which the electrode structure is coupled to an active semiconductor film in order to form the photovoltaic device.

19. The method of claim 18, wherein an atmosphere in which the target(s) used in forming the electrode and/or the buffer film is sputtered includes both argon and oxygen gas and has an oxygen gas to total gas ratio of from 0.00001 to 0.0025.

20. The method of claim 18, wherein the semiconductor film comprises amorphous silicon or CdTe.
